(19) United States
(12) Patent Application Publication
(10) Pub. No.: US 2014/0034117 A1
(43) Pub. Date: Feb. 6, 2014

(54) PHOTOVOLTAIC CONCENTRATOR RECEIVER AND ITS USE

(71) Applicants: Maike Wiesenfarth, Freiburg (DE); Oliver Wolf, Weisweil (DE); Joachim Jaus, Freiburg (DE); Gerhard Peharz, Gleisdorf (AT); Fabian Eltermann, Freiburg (DE)

(72) Inventors: Maike Wiesenfarth, Freiburg (DE); Oliver Wolf, Weisweil (DE); Joachim Jaus, Freiburg (DE); Gerhard Peharz, Gleisdorf (AT); Fabian Eltermann, Freiburg (DE)

(73) Assignee: FRAUNHOFER-GESELLSCHAFT ZUR FOERDERUNG DER ANGEWANDTEN FORSCHLUNG E.V., MUNICH (DE)

(21) Appl. No.: 13/261,690

(22) PCT Filed: Jan. 26, 2011
(86) PCT No.: PCT/EP11/00333

§ 371 Date: Oct. 10, 2013

(51) Int. Cl. H01L 31/052; H01L 31/0687

(52) U.S. Cl. CPC H01L 31/0522; H01L 31/0687
USPC 136/255; 136/259

(57) ABSTRACT

The present invention relates to a photovoltaic (PV) concentrator receiver for concentrated illumination which comprises a substrate with at least one solar cell, wherein on the front surface of the substrate and the at least one solar cell an encapsulation material and a cover plate are disposed. The edges of the receiver are protected by a frame. The inventive PV concentrator receiver can be used for producing electricity from concentrated solar radiation.

The present invention relates to a photovoltaic (PV) concentrator receiver for concentrated illumination which comprises a substrate with at least one solar cell, wherein on the front surface of the substrate and the at least one solar cell an encapsulation material and a cover plate are disposed. The edges of the receiver are protected by a frame. The inventive PV concentrator receiver can be used for producing electricity from concentrated solar radiation.

The invention relates to the area of technologies where photovoltaic cells produce electricity from concentrated solar radiation. Here, in particular highly concentrated solar radiation is focussed on a small area. In this application this small area is of interest. In the focus, there are several solar cells that are mounted to a dense array and eclectically connected to a module/receiver. The area of the solar module is in the range of cm² up to some 100 cm². One option to concentrate the solar radiation is to reflect the radiation by mirrors that are adjusted so that the beam meets the receiver. The solar radiation ratio can reach more than 1000. In current applications the concentration is between 200 and 1000. The complete system of mirrors and receiver with the solar cells are components of a large open concentrator (dish concentrator) system. They are mounted to a two axis tracking system that follows the sun (US 2004/0103680 A1), which e.g. can be a parabolic or paraboloid mirror dish system where there is a dense array solar module in the centre (=central receiver). Such a,system is developed and commercialised e.g. by the company Zenith Solar LTD., Israel.

The solar cells of the receiver can be silicon solar cells. To increase the system efficiency also multi-junction solar cells are used. In multi-junction solar cells, pn-junctions with different energy band gaps are assembled on top of each other. In the top solar cell, the energy with the lowest wavelength is absorbed hence the cell has the highest energy band gap. The pn-junctions below have decreasing energy band gaps. In this way, the energy spectrum of the solar radiation can be used more efficiently as thermalisation and transmission losses are decreased. The multi-junction solar cells are more expensive. In concentrating photovoltaic systems, the area populated with solar cells is small and therefore it is still cost effective to use this type of cells. For multi-junction solar cells usually the semiconductor germanium or III-V compound semiconductors are used. III-V semiconductors are compounds from the 3. and 5. main group of the periodic table of the elements (e.g. Gallium arsenide or Gallium indium phosphide).

An important aspect of solar cells is the protection against outdoor conditions. Humidity and the solvents in rain like salt can cause corrosion. Hail, dust, wind can stress the cells and the fragile electrical interconnections mechanically. Water or water vapour can cause corrosion to the metallisation on the solar cells, the electrical contacts or the adhesive/solder that is used to bond the solar cell to the substrate. If germanium is used as substrate for the multi-junction solar cell, the germanium oxidises with oxygen and water to germanium oxide (GeO₂).

If the front side of the solar cells are covered with encapsulation material, the material needs to be highly transparent. The reason is that, as a first aspect, first light that is reflected or absorbed in the encapsulation can not be converted into electricity by the solar cells. As a second aspect, due to the absorbed light in the encapsulation layer the temperature will increase in the material and could rise above the operation temperature.

For open concentrator (dish concentrator) systems (the application of central receivers) with up to 1000 times concentration there are no solutions known where solar cells are directly potted with a transparent encapsulation material.

For silicone flat plate modules ethylene vinyl acetate (EVA) is used (U.S. Pat. No. 7,049,803 B2). As the UV stability of EVA is limited, EVA is not used in concentrator dense arrays.

Another encapsulation method is used in different concentrator systems (closed concentrator systems) where light is concentrated by lenses on small solar cells. Various lenses are assembled to lens plates that form a module. The protection method of these systems is to have housings that are sealed to the environment. The housing consists of the lens plate in the front, a frame to the sides and a base plate where the solar cells are mounted to (A. L. Luque, V. M. Andreev: Concentrator Photovoltaic, Chapter: The FLATCON System from Concentrix Solar, A. W. Bett, H. Lerchenmüller, p. 301 to 319). In this application the encapsulation material is not irradiated by concentrated solar radiation.

In open concentrator (dish concentrator) systems the solar receiver (e.g. 100 cm²) are assembled in the focus and illuminated with high concentrated solar radiation (e.g. 1000 times). In this case the mirror area would be 12.5 m² (assuming optical losses of 20%). On the module, there are various solar cells that are mounted closely together (dense array). Usually each solar cell is equipped with a bypass diode that protects the solar cell in case of defects or inhomogeneous illumination. The heat sink of the module is the substrate where the solar cells are mounted to. Mostly it is actively cooled, e.g. with a high efficient water cooler.

The mirror concentrator is very large (e.g. 12.5 m²) compared to the receiver with an area of about 100 cm². Therefore the receiver will be protected against outdoor conditions separately to the mirror system. This means that the requirements for the receiver encapsulation are very high as it is illuminated with concentrated radiation. The highest concentration is in the centre of the beam. The tracking system follows the sun so that the focus of the light is on the photovoltaic cells. During normal operation the edges of the receiver will be illuminated only with diffused light and low concentration. When the system moves into storm position, has a tracking error or when it begins with tracking, the focus moves across the complete encapsulation. Also there is an off-axis beam damage test in the standard IEC 62108 for concentrator modules. Here the module needs to survive when the focus is kept at a critical position (e.g. the encapsulation frame) for 15 minutes at DINI 800 W/m². Thus, all parts of the encapsulation need to withstand the high thermal stress due to the concentration of the beam centre.

An advantage of having a transparent potting material that is directly covering the solar cells is the increase of efficiency due to internal reflection. This means that the refractive indices of the solar cell surface (antireflection coating) are adapted to the refractive index of the potting material. Hence, there are little losses due to reflection on the interface solar cell/pottant. As there is an air/glass interface above the solar cell light that is reflected e.g. on the metallisation of the solar cell will be reflected to the glass/air interface and from there back to the solar cell. The radiation that is reflected back to the solar cell can be converted into electricity and hence will increase the efficiency of the module.

A triple junction solar cell absorbs the light up to a wavelength of almost 1770 nm. The reason is that the energy band gap of the lowest solar cell (for germanium) is 0.7 eV. That means the encapsulation material above the solar cell needs to transmit the light up to 1770 nm otherwise the efficiency decreases. In addition all energy that is absorbed in the encapsulation material will increase the temperature in the material and it might rise above the operating temperature.

As encapsulation material, silicones can have high transmission properties. Moreover, silicones have good handling properties as processing and curing temperatures are between 20 and 150° C. depending on the manufacturer. Operating temperatures are between 150° C. and 200° C. Usually materials with high transmission coefficients have a low thermal conductivity coefficient, what applies to silicones as well. For example, the silicone “Dow Corning Sylgard 184? has a thermal conduction coefficient of 0.18 W/(m*K). This means that the heat transfer of the absorbed energy to the substrate is low. Also the heat transfer by radiation is low as the illuminated area of the receiver is small and the temperature in the encapsulation material during operation should be below 200° C. To reduce the absorbed energy in the potting material (e.g. silicone) the layer thickness needs to be minimised. It should have a thickness of about 0.3 mm and is limited to 1 mm.

Silicone materials are hydrophobic and water resistant. On the other hand, silicones are not water vapour permeable. Therefore on top of the silicone a water vapour sealing is needed. This can be a glass plate. The glass properties have the same requirements as the silicone. The transmission needs to be high. Therefore a borosilicate glass can be used. Borosilicate glass mainly consists of a high content (up to 80%) of silicon dioxide (Si₂O) and boron trioxide (B₂O₃) (7 to 13%). Because of its low thermal expansion coefficient (3.3*10⁻⁶ l/K) the glass type withstands temperature differences within the material. It is mostly used for laboratory glass. The thickness of the glass is preferably between 1 and 4 mm.

Starting from this prior art was the object of the present invention to provide a protection for the edges of a photovoltaic concentrator receiver. A further object of the present invention was to improve the illumination concentration of such modules.

This technical problem is solved by the photovoltaic concentrator receiver with the features of claim 1 and the use of this receiver with the features of claim 16. The further dependent claims describe preferred embodiments.

According to a first aspect, present invention provides a photovoltaic (PV) concentrator receiver for concentrated illumination is provided, which comprises at least one substrate with at least one solar cell, wherein on the front surface of the substrate and the at least one solar cell an encapsulation material and a cover plate are disposed.

The inventive photovoltaic concentrator receiver is characterized by a protection of the edges of the receiver by using a frame, which is spaced apart from the encapsulation material and the cover plate.

At the edges of the receiver, silicone is deposited with a cover plate on top. Both parts have to be shielded from direct sunlight as well as mechanical stress. This problem was solved by using a frame above the cover plate, which is spaced apart from the encapsulation material. The spacing allows that the encapsulation material can expand if the temperature increases due to irradiation. The spacing between the encapsulation material of the frame can be in the range of 0.1 mm to 2 mm, preferably from 0.2 mm to 1.5 mm.

As encapsulation material a material is selected having highest transparency of at least 85% in average between 400 nm and 2000 nm, especially in low wavelength between 350 nm and 400 nm a transmission of at least 70%. The material is processed in a liquid phase (viscosity between 200 and 40000 mPas at 20 to 30° C. and then cured at temperature, time, UV light or humidity until it becomes stable. (In contrary to EVA which is processed in a lamination process as a film or sheet to the solar cell. This is not possible in this application because of the fragile interconnecttion.) The most preferred material currently is silicone.

Preferably, the cover material is a temperature-resistant glass with a transparency of at least 85% in average between 400 nm and 2000′ nm and at least 70% between 350 nm and 400 nm and resistance to thermal tension of at least 100 K temperature difference across the transparent material. This material can be selected from the group consisting of borosilicate glass, quartz glass, white glass and composites or laminates thereof.

In a further preferred embodiment, an anti-reflected coating is deposited on the cover plate.

Moreover, it is preferred that the frame is in thermal contact with the substrate.

In a further preferred embodiment the frame has a cooler, which is cooled by a heat transfer fluid. The cooler can be cooled actively by microchannel coolers and/or ink-jet coolers, and/or the cooler is cooled passively by heat pipes and/or cooling fins.

It is preferred that the frame has a reflective surface to reduce or avoid heat adsorption by the frame.

Preferably the frame material selected from the group consisting of copper, aluminum, aluminum alloys, aluminum silicon alloys, aluminum silicon carbide alloys, steel, ceramics and composites thereof.

The frame is preferably made of aluminium. The frame needs a reflective surface to reduce the absorption of solar energy during operation, but also when the focus is tracked over the frame to the solar cells. This is why an aluminium alloy with a high Al content is needed. For example pure aluminium (Al content>99%), an Al—Mg alloy or Al—Mg—Mn alloy can be used. The reflexion of aluminium can be increased by depositing reflective coatings, by mechanical, electrical or chemical polishing. The oxide layer on the surface gives long term stability. The reflexion is more than 75%.

During operation the temperature stability of aluminium is limited (e.g. 250° C.) depending on the alloy. This is why the frame needs to have a good thermal contact to the heat sink. Here either the front surface, side (see FIG. 8 and FIG. 10) or the back surface (see FIG. 11) can be used depending on the design of the heat sink.

Moreover, it is preferred that the frame is modified to act as a secondary optic, wherein the walls of the frame are angled to reflect the scattered or misaligned radiation back to the at least one solar cell.

For this option, the front side of the frame is designed to work as a secondary optics. The surface of the aluminium is reflective. The slope and size of the surface can be design to reflect diffused light on the solar cell. It can also be designed to homogenise the flux distribution on the area populated with solar cells. Especially the flux on the solar cells in the border area usually is lower than in the centre. In this way the acceptance angle can be increased. Misalignment of the tracker can be compensated. The total electrical efficiency of the system can be increased.

Moreover, it is preferred that the space between encapsulation material, cover plate and frame is at least partially filled with a temperature-resisting sealing material, preferably selected from the group consisting of viton sealing, glass fiber, ceramic sealing, graphite sealing, silicone, epoxy, polyurethane and composites thereof. If this space is at least partially filled with such a temperature-resistant material, the receiver is protected against vapor. This material has the function of a high-temperature-resistant and elastic sealing.

Another option is to leave the space unfilled. For this case, water vapor will infiltrate the silicone, but will evaporate as soon as the temperature increases. The space between the edge and the solar cell needs to be designed that humidity does not get to the solar cell. In this context, adequate conditions have to be defined. Whereby the conditions defined in IEC 62108 can serve as a guideline. One condition to be fulfilled is the module withstands the damp heat and humidity-freeze test.

It is preferred that the substrate surface or cover glass surface is modified to improve the adhesion of the encapsulation material on the substrate. Different process like plasma treatment, flaming, pyrolysis, ultrasonic cleaning, adhesion promoter or chemical solvents can be suitable.

In the concentrator receiver the at least one photo-voltaic cell is preferably a multi-junction solar cell, more preferably a germanium or a III-V-semiconductor solar cell.

The PV concentrator receiver can have a rectangular, angular or round shape.

There is also the possibility to have cooling channels in the metal frame. A separate cooling cycle or the same as used to cool the heat sink can be used. If the same cooling cycle is used, it is preferred that first the solar cells are cooled and afterwards the frame. The reason is that the efficiency of the solar cell decreases with the temperature.

The frame should not shade the solar cells. That is why the potting material and the glass are larger than the area populated with solar cells.

According to a first embodiment, the frame is made of aluminium. The problem with a metal frame is that an aluminium with a length of 20 cm and a thermal expansion coefficient of 23 10⁻⁶ l/K will expand by 4.6*10⁻³ mm/K whereas the glass expands by 0.6 10⁻³ mm/K. The silicone will expand by 62*10⁻³ mm/K as the linear coefficient of expnsion is 310 10⁻⁶ 1/K. For a temperature difference of 100 K it means a difference in length of 0.4 mm between aluminium and glass. This will introduce stress to the interconnection between heat sink, frame and front glass plate. The interface between the metal and the heat sink needs to be seal and electrically isolated (if directly mounted to the electrical terminals). That means an electrically insulating adhesive has to be used which usually has a low thermal conductivity. The interconnection between the front glass plate and the frame needs to be seal and resistant against solar radiation. As the glass is highly transparent the interface is illuminated by concentrated radiation. It will absorb most of the energy hence it needs to be temperature resistant, but also needs to be resistant to the radiation (e.g. resistant to the UV light).

According to a second embodiment, a glass frame instead of an aluminium frame is used, which will reduce the difference in thermal expansion. The problem is to find a way of mounting the glass. It needs to be attached to the front glass and the heat sink to give a connection and a sealing. Therefore an adhesive can be used. The difficulty is that on the top side a transparent adhesive is required. Usually these materials (like UV-curing adhesive) are not heat resistant. Also it is possible that there are chemical reactions between the adhesive and the silicone. For example there can be diffusion process which will change the properties of the silicone or adhesive. For example the silicone can loose its strength/hardness. If the glass is mounted using the same silicone as used as potting material then the gluing areas are not water vapour permeable. There is another disadvantage next to the problems that the temperature in the frame and bonding layers will be a critical area and thermal conductivity properties of electrical insulating adhesives and glass are poor. It is that glass is difficult to process. So it is costly to give glass a defined shape to balance for example different heights on the surface.

According to a third embodiment, the open edges between glass and silicone are sealed with a flexible plastic moulding material. This could be a thermal conductive sealing which could be a silicone rubber with fillings to increase the thermal conductivity.

The colour of the silicone would depend on the filling and would be black in case of carbon/grime. Then the problems are the high energy absorption that needs to be conducted to the heat sink. The temperature resistance is still limited to about 300° C. So this will be critical as the thermal conductivity (e.g. 0.3-0.4 W/(m*K)) is low. Again if it is a silicone material it is not water vapour permeable. Also chemical reactions, e.g. diffusion processes with the transparent silicone, are likely and the properties of the silicones can change.

A fourth alternative for a frame material is using a different metal or alloy. This could be copper or brass which has higher heat conductivity and higher temperature stability.

The present invention will now be described in detail with reference to the following figures, which by no means shall limit the scope of the invention.

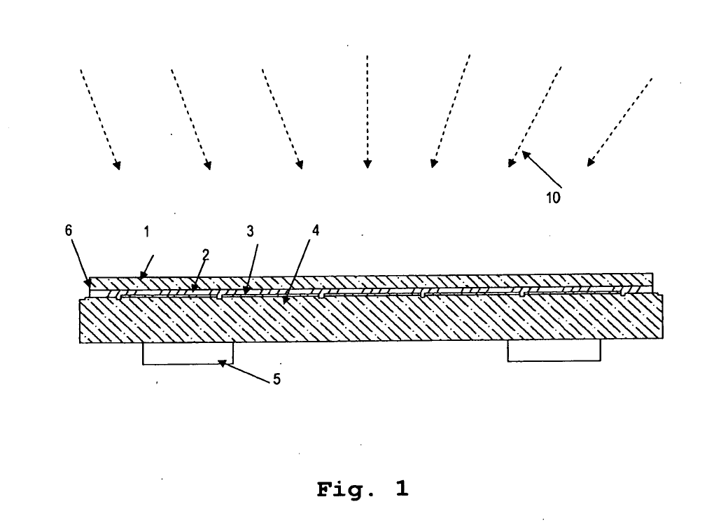

FIG. 1 shows a cross-section of a photovoltaic concentrator receiver according to the prior art.

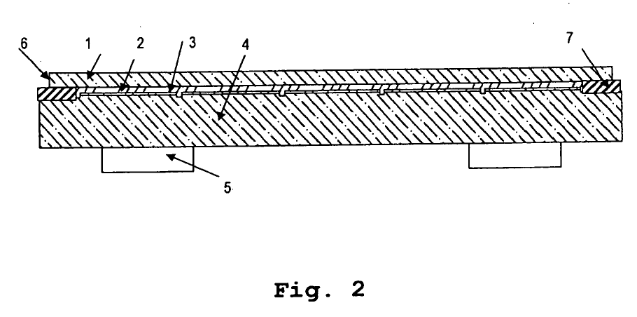

FIG. 2 shows a cross-section of a photovoltaic concentrator receiver according to the present invention.

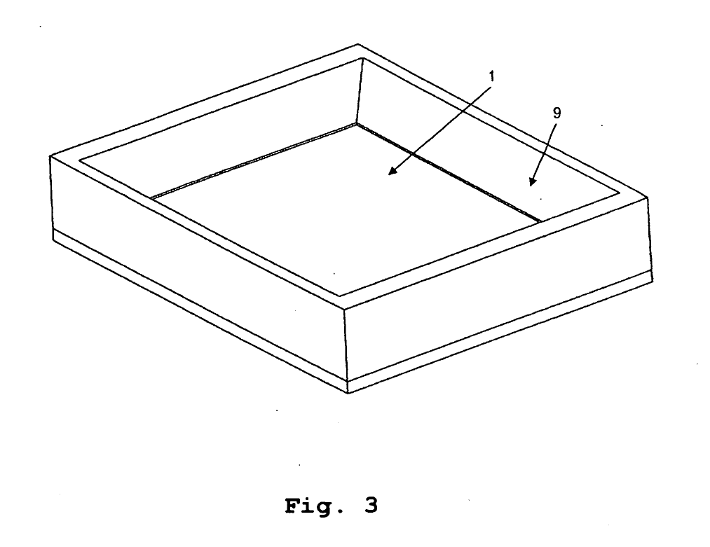

FIG. 3 shows the photovoltaic concentrator receiver according to the present invention in the top view.

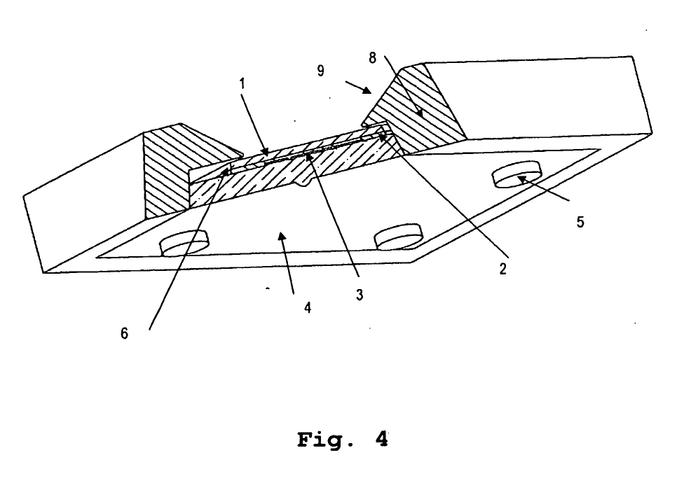

FIG. 4 shows a cross-section of one embodiment of the photovoltaic concentrator receiver according to the present invention.

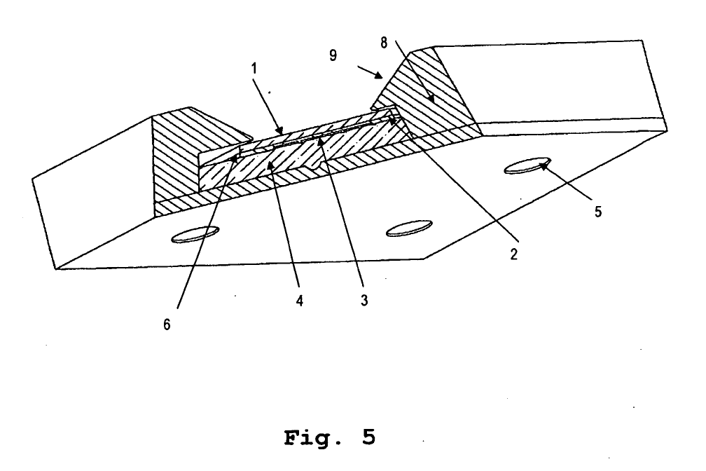

FIG. 5 shows a cross-section of another embodiment of the receiver of the present invention.

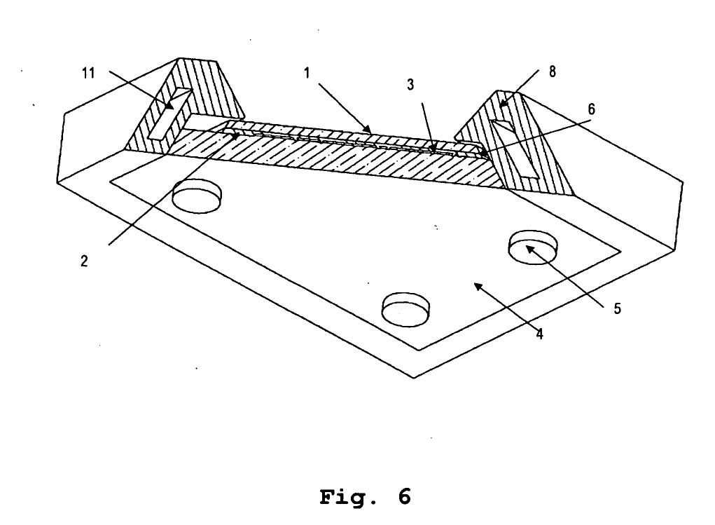

FIG. 6 shows a cross-section of another embodiment of the receiver of the present invention.

In FIG. 1 a photovoltaic concentrator receiver according to the prior art is illustrated. The solar cell is based on a heat sink 4, which is covered on the front side with solar cells 3. These solar cells 3 are embedded in an encapsulation material 2, which to the front side is covered by a glass plate 1. The edges of the receiver 6 according to the prior art are not protected. The receiver is illuminated by concentrated solar radiation 10.

In FIG. 2 a photovoltaic concentrator receiver according to the present invention is demonstrated. On the heat sink 4 solar cells 3 are arranged, which are embedded in an encapsulation material 2. This encapsulation material 2 is covered by a glass plate 1. In contrast to the prior art embodiment of FIG. 1, according to the present invention the edges of the receiver 6 are protected with the frame 7.

In FIG. 3 a top view of the inventive photovoltaic concentrator receiver is illustrated. The glass plate 1 is surrounded by a frame which is angled to serve as a secondary optics 9.

In FIG. 4 a cross-section of an embodiment of the photovoltaic concentrator receiver of the present invention is illustrated. According to this figure, the heat sink 4, the solar cells 3, the encapsulation material 2 and the glass cover 1 are surrounded at its edges 6 by a metal frame 8.

In FIG. 5 a further embodiment is shown similar to the embodiment of FIG. 4. The difference in this figure is that the thermal contact of the frame to the heat sink is the back surface of the heat sink.

In FIG. 6 a cross-section of a further embodiment of the present invention is shown, which differs from the embodiments of FIGS. 4 and 5 by the cooling channels 11 for active cooling of the metal frame 8.

1-16. (canceled)

17. A photovoltaic (PV) concentrator receiver for concentrated illumination comprising at least one substrate with at least one solar cell wherein on the front surface of the substrate and the at least one solar cell an encapsulation material and a cover plate are disposed, wherein the edges of the receiver are protected by a frame which is spaced apart from the encapsulation material and the cover plate

18. The PV concentrator receiver of claim 17, wherein the encapsulation material is silicone.

19. The PV concentrator receiver of claim 17, wherein the encapsulation material is liquid during processing and thereby has a viscosity of 200 to 40000 mPas at 20 to 30° C.

20. The PV concentrator receiver of claim 17, wherein the cover material is a temperature resistant material with a transparency of at least 85% in average between 350 nm and 2000 nm selected from the group consisting of borosilicate glass, quartz glass, white glass and composites or laminates thereof.

21. The PV concentrator receiver of claim 17, comprising an anti-reflection coating deposited on the cover plate.

22. The PV concentrator receiver of claim 17, wherein the frame is in thermal contact with the substrate.

23. The PV concentrator receiver of claim 17, wherein the frame has a cooler which is cooled by a heat transfer fluid.

24. The PV concentrator receiver of claim 23, wherein the cooler is cooled actively by micro channel coolers and/or ink-jet coolers, and/or the cooler is cooled passively by heat pipes and/or cooling fins.

25. The PV concentrator receiver of claim 17, wherein the frame has a reflective surface to reduce heat absorption.

26. The PV concentrator receiver of claim 17, wherein the frame is modified to act as a secondary optic wherein the walls of the frame are angled to reflect the scattered or misaligned radiation back to the at least one solar cell.

27. The PV concentrator receiver of claim 17, wherein the frame material is selected from the group consisting of copper, aluminium, aluminium alloys, aluminium silicon alloys, aluminium silicon carbide alloys, steel, ceramics and composites thereof.

28. The PV concentrator receiver of claim 17, wherein the space between encapsulation material, cover plate and frame is at least partially filled with a temperature resistant sealing material, preferably selected from the group consisting of viton sealing, glass fibre, ceramic sealing, graphite sealing, silicone, epoxy, polyurethane and composites thereof.

29. The PV concentrator receiver of claim 17, wherein the surface of the substrate is modified to improve the adhesion of the encapsulation material on the substrate and glass cover.

30. The PV concentrator receiver of claim 17, wherein the at least one solar cell is a multi-junction solar cell, preferably a germanium or a III-V semiconductor solar cell.

31. The PV concentrator receiver of claim 17, wherein the PV concentrator receiver has a rectangular, angular or round shape.

32. A method of producing electricity from concentrated solar radiation utilizing the PV concentrator receiver of claim 17.
